(19) United States
(12) Patent Application Publication
(10) Pub. No.: US 2003/0156635 A1
(43) Pub. Date: Aug. 21, 2003

(54) Adaptive filtering with DC bias compensation

(76) Inventors: Ivan Jesus Fernandez-Corbaton, San Diego, CA (US); John Smee, San Diego, CA (US); Srikant Jayaraman, San Diego, CA (US)

Correspondence Address: Qualcomm Incorporated, Patents Department, 5775 Morehouse Drive, San Diego, CA, 92121-1714, US

(21) Appl. No.: 10/081,857

(22) Filed: Feb. 20, 2002

(51) Int. Cl. H03H 7/30

(52) U.S. Cl. 375/232

(57) ABSTRACT

Systems and techniques for filtering digital samples is disclosed in which a number of filter coefficients are adapted, and the digital samples are filtered by applying one of the filter coefficients to a parameter, applying each remaining filter coefficient to one of the samples, and combining the parameter and the samples. The adaptation of the filter coefficients is a function of the combined parameter and digital samples. It is emphasized that this abstract is provided to comply with the rules requiring an abstract which will allow a searcher or other reader to quickly ascertain the subject matter of the technical disclosure. It is submitted with the understanding that it will not be used to interpret or limit the scope or the meaning of the claims.

### BACKGROUND

1. Field

The present invention relates generally to communications systems, and more specifically, to systems and techniques for adaptive filtering with DC bias compensation.

2. Background

Communications systems are used for transmission of information from one device to another. The devices included in the communications systems typically have either a transmitter, a receiver, or both. The function of the transmitter is to encode information and modulate the encoded information into an analog signal suitable for transmission over a communications medium. The function of the receiver is to detect the analog signal in the presence of noise, demodulate the detected analog signal to recover the encoded information, and decode the information.

In the process of demodulating the analog signal, the receiver typically performs an analog to digital conversion to obtain digital samples of the detected analog signal. The device used for this purpose is typically an analog-to-digital converter (ADC). Conceptually, this device operates by comparing the input voltage of the detected analog signal to a fixed reference voltage and quantizing the difference into a digital sample with a specified number of bits. The fixed reference voltage can be interpreted as the “zero” of the ADC, or equivalently, as the input signal voltage which translates to a “zero” for the digital sample.

The reference voltage should always be constant. However, due to various practical factors like noise, tolerance of the ADC components, etc., the reference voltage is typically not fixed. This introduces a bias (possibly slowly time-varying) in the digital output. In the frequency domain, this bias causes a narrow noise peak near the zero frequency (DC) of the signal spectrum. Furthermore, some receiver configurations may introduce a bias in the detected analog signal even before the ADC.

In receivers employing an adaptive filter at the output of the ADC, the DC bias may have a particularly undesirable effect. Since the adaptive filter shapes its frequency response based on the signal and noise power spectral densities, a narrow noise peak near the zero frequency forces the adaptive filter to synthesize a corresponding null near DC. Not only does this increase signal distortion, it may also limit the adaptive filter's ability to compensate for inter-symbol interference (ISI) and multipath reflections.

### SUMMARY

In one aspect of the present invention, a method of filtering a plurality of samples includes adapting a plurality of filter coefficients, and filtering a plurality of samples by applying one of the filter coefficients to a parameter, applying each remaining filter coefficient to one of the samples, and combining the parameter and the samples, wherein the adaptation of the filter coefficients is a function of the combined parameter and samples.

In another aspect of the present invention, a receiver includes an analog-to-digital converter configured to sample an analog signal to produce a plurality of samples, and a filter having a coefficient generator configured to adapt a plurality of filter coefficients, the filter being configured to apply one of the filter coefficients to a parameter, apply each of the remaining filter coefficients to one of the samples, and combine the parameter and the samples, the adaptation of the filter coefficients being a function of the combined parameter and samples.

In yet another aspect of the present invention, a filter includes a delay element configured to serially receive a plurality of samples, a coefficient generator configured to adapt a plurality of coefficients, a first multiplier configured to multiply said one of the filter coefficients with the parameter, a second multiplier configured to multiply each remaining filter coefficient with one of the samples from the delay element, and an adder configured to sum the parameter and the samples, wherein the adaptation of the filter coefficients is a function of the summed parameter and samples.

In a further aspect of the present invention, computer-readable media embodying a program of instructions executable by a computer program performs a method of adapting filter coefficients including adapting a plurality of filter coefficients, and filtering a plurality of samples by applying one of the filter coefficients to a parameter, applying each remaining filter coefficient to one of the samples, and combining the parameter and the samples, wherein the adaptation of the filter coefficients is a function of the combined parameter and samples.

In yet a further aspect of the present invention, a filter includes means for adapting a plurality of filter coefficients, and means for filtering a plurality of samples by applying one of the filter coefficients to a parameter, applying each of the remaining filter coefficients to one of the samples and combining the parameter and the samples, wherein the adaptation of the filter coefficients is a function of the combined parameter and samples.

It is understood that other embodiments of the present invention will become readily apparent to those skilled in the art from the following detailed description, wherein it is shown and described only exemplary embodiments of the invention by way of illustration. As will be realized, the invention is capable of other and different embodiments and its several details are capable of modification in various other respects, all without departing from the spirit and scope of the present invention. Accordingly, the drawings and detailed description are to be regarded as illustrative in nature and not as restrictive.

### BRIEF DESCRIPTION OF THE DRAWINGS

Aspects of the present invention are illustrated by way of example, and not by way of limitation, in the accompanying drawings in which like reference numerals refer to similar elements:

FIG. 1 is a functional block diagram of a communications device employing an exemplary receiver;

FIG. 2 is a functional block diagram of an exemplary adaptive filter which can be used with the receiver of FIG. 1;

FIG. 3 is functional block diagram of a communications device employing an exemplary receiver with a DC notch filter;

FIG. 4 is a functional block diagram of a communications device employing an exemplary receiver arrangement capable of supporting multiple antennas;

FIG. 5 is a functional block diagram of a code division multiple access (CDMA) communications system having a subscriber station with an exemplary adaptive filter; and

FIG. 6 is a functional block diagram of the subscriber station of FIG. 5.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other embodiments. The detailed description includes specific details for the purpose of providing a thorough understanding of the present invention. However, it will be apparent to those skilled in the art that the present invention may be practiced without these specific details. In some instances, well known structures and devices are shown in block diagram form in order to avoid obscuring the concepts of the present invention.

In an exemplary communications device, an adaptive filtering process can be performed which corrects for DC bias. This can be achieved by adapting a number of filter coefficients during the transmission of a known sequence from a remote source. One of the filter coefficients can then be applied to a parameter to produce a weighted parameter, and the remaining filter coefficients can be applied to the digital samples to produce a number of weighted digital samples. The weighted parameter can be combined with the weighted digital samples to produce estimates of the transmitted symbols. The adaptation of the filter coefficients can be performed using any classical least square algorithm including a “least mean square” (LMS) algorithm, a “recursive least squares” algorithm (RLS), a direct least squares matrix inversion of an estimated autrocorrelation matrix, or any other algorithm known in the art.

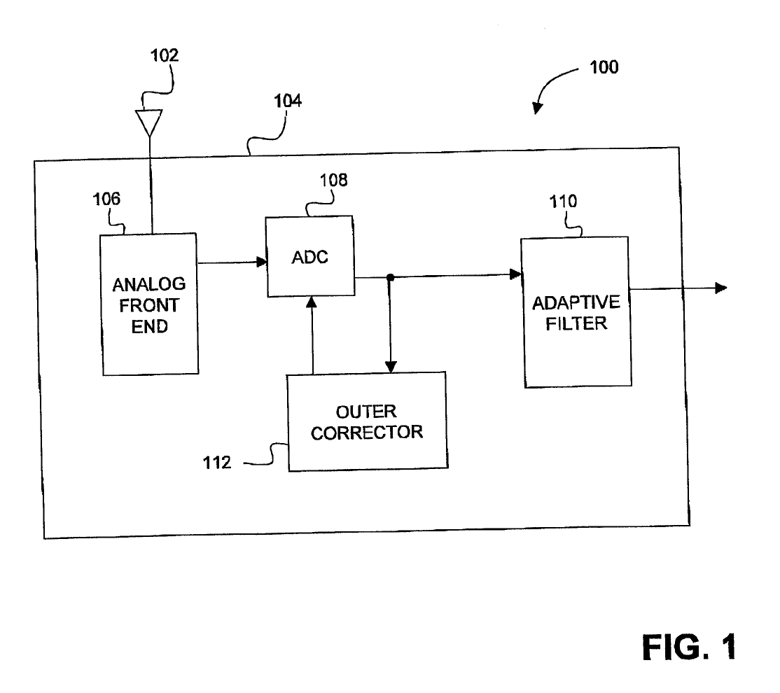

FIG. 1 is a functional block diagram of a communications device employing an exemplary receiver. The communications device 100 includes an antenna 102 configured to receive a wireless transmission. Alternatively, the communications device 100 can be configured to receive a transmission by way of cable, fiber optic link, digital subscriber line, or any other communications medium known in the art.

In the embodiment shown in FIG. 1, the transmission received by the antenna 102 can be provided to a receiver 104. The receiver can be based on a heterodyne complex (I-Q) architecture. For ease of explanation, the exemplary receiver will be depicted functionally without reference to separate I (in-phase) and Q (quadrature) channels. The receiver 104 may have an analog front end (AFE) 106 which amplifies, filters and downconverts the transmission to an analog baseband signal. The analog baseband signal from the AFE 106 can be provided to an ADC 108 to produce digital baseband samples. The digital baseband samples from the ADC 108 can then be provided to an adaptive filter 110.

The adaptive filter 110 can be used to compensate for ISI which occurs as a result of the spreading of a transmitted symbol pulse due to the dispersive nature of the communications medium which results in an overlap of adjacent symbol pulses. The adaptive filter 110 may be implemented with a transversal filter, such as a “finite impulse response” (FIR) filter. Alternatively, the adaptive filter 110 can be implemented with a “decision feedback equalizer” (DFE), or any other filter known in the art.

The adaptive filter 110 may be implemented with a multiple-tap delay line. The output of the taps can be weighted and summed to generate a “soft estimate” of the transmitted symbol. The tap coefficients can be adapted to subtract the interference from symbols that are adjacent in time to the desired symbols. The adaptive filter 110 can use a prescribed algorithm, such as a “least mean square” (LMS) algorithm, a “recursive least squares” (RLS) to estimate the tap coefficients, or any other algorithm known in the art. The “soft estimate” generated by the adaptive filter 110 can be used by a decision making device such as a slicer (not shown). The slicer applies a threshold operation in order to arrive at a “hard estimate” of the transmitted symbol.

The exemplary communications device will be described from hereon with the assumption that the received transmission is sampled by the ADC 108 at a rate of one sample per symbol period T, and that the adaptive filter 110 is an T-spaced filter. These assumptions are made for illustrative purposes only, and those skilled in the art will readily appreciate that the inventive concepts described throughout can be extended to other sampling rates and filter tap spacings.

The digital baseband samples from the ADC 108 can be represented by a stream of digital samples x(k) that contain the transmitted symbols y(k), multipath interference, ISI and noise. This stream {x(k)} can be filtered by the adaptive filter 110 to produce estimates ŷ(k) of the transmitted symbols. For an N-tap adaptive filter, the symbol estimates ŷ(k) can be expressed as:

ŷ(k)=H^{H}X(k) (1)

where k is the temporal index, ŷ(k) is the estimate of the k-th transmitted symbol y(k), H is a column vector of length N containing the filter coefficients, the superscript ^{H} denotes the Hermitian operation, and x(k) is a column vector of length N containing N consecutive digital samples from the ADC 108. The column vector H for the filter coefficients can be represented as:

$$H = [ \begin{matrix}{h}_{0} \\ {h}_{1} \\ {h}_{2} \\ ⋮ \\ {h}_{N - 1}\end{matrix} ] \qquad ( 2 )$$

A common arrangement for the column vector x(k)for the digital samples with N being odd can be expressed as:

$$X ( k ) = [ \begin{matrix}x ( k - \frac{N - 1}{2} ) \\ ⋮ \\ x ( k + \frac{N - 1}{2} )\end{matrix} ] \qquad ( 3 )$$

Those skilled in the art will appreciate that there could be a variety of other ways to construct the column vector x(k) for the digital samples.

The standard criterion for optimizing the filter coefficients H of the adaptive filter 110 is by the mean square error (MSE) of the symbol estimates which can be expressed as:

e(H)=E|y(k)−ŷ(k)|² (4)

where E{ . . . } denotes statistical expectation. Optimal performance in terms of maximizing signal-to-noise ratio is generally achieved by minimizing the MSE. This can be accomplished by adapting the filter coefficients with a least square algorithm, or other known algorithm, during the pilot sequence of the transmission. Since the pilot sequence is known, a priori, the MSE can be computed from the soft symbol estimates generated by the adaptive filter 110.

A typical LMS algorithm is a steepest descent search algorithm that uses a very efficient estimate of the gradient (the product of the MSE and the digital baseband samples) towards minimization of the MSE and can be represented as follows:

H(k+1)=H(k)+μX(k)e(k)^{H} (5)

Equation (5) represents an adaptation step of the typical LMS algorithm where μ is a gain constant (or adaptation constant) that regulates the speed and stability of adaptation. As can be seen from equation (5), the LMS algorithm can be implemented in a practical system without squaring, averaging, or differentiation.

In at least one embodiment of the described communications device, a digital correction scheme can be implemented by the adaptive filter 110 to compensate for DC bias introduced by the AFE 106, the ADC 108 and/or any other receiver component. The digital correction scheme can be implemented with a modified “minimum mean square error” (MMSE) computation from which the LMS algorithm can be derived.

A digital correction scheme implemented in the adaptive filter may provide certain performance advantages. By way of example, the DC bias compensation may be on a fractional basis due to the extended bit width of the filtered digital samples due to the filtering process itself. Attempting to correct a DC bias smaller than 1 LSB on the digital baseband samples input to the adaptive filter could result in either a performance loss due to additional quantization noise or an increase in the bit width of the digital baseband samples which may lead to additional hardware cost to implement the adaptive filter.

A feedback circuit employing an outer correction loop 112 may be used to control the clipping of the digital baseband samples by the ADC 108 should the DC bias become excessive. Since the ADC 108 uses a finite number of bits to represent the analog baseband signal, clipping may occur if the analog baseband signal falls outside the numerical range that can be represented with the specified number of bits. Once the digital baseband samples are clipped, information may be lost reducing the performance of the adaptive filter.

The outer correction loop 112 provides a means to control the clipping to an acceptable level. The design and implementation of the outer correction loop 112 is well known. For purposes of illustration, the outer correction loop 112 can be designed to monitor the DC bias at the output of the ADC 108. The outer correction loop 112 sends a feedback a signal to the ADC 108 to compensate for the DC bias if its absolute value exceeds a threshold, which may be predetermined by the designer of the system. The DC bias can be compensated for by adjusting the fixed reference voltage of the ADC 108. The adaptive filter 110 can be used to remove any residual DC bias whose absolute value at the output of the ADC 108 does not exceed the threshold. By digitally correcting the residual DC bias in the adaptive filter 110, the outer correction loop 112 does not need to be as stringent as those used in the past, thus allowing a cheaper and more flexible implementation.

The DC bias in the digital baseband samples can be modeled by adding a fixed complex number to the digital baseband samples from an ideal bias-free ADC as follows:

x′(k)=x(k)+b (6)

where the x(k) denotes the digital baseband samples from an ideal bias-free ADC, b represents the DC bias, and x′(k) denotes the actual digital baseband samples generated by the ADC. To digitally correct the symbol estimates ŷ(k) for DC bias, one or more dimensions may be added to the column vectors of the filter coefficients and digital baseband samples. This approach yields modified symbol estimates which can be represented as:

$$\hat{y} ( k ) = {C}^{H} Z ( k ) = {[ \begin{matrix}H \\ λ\end{matrix} ]}^{H} [ \begin{matrix}{X}^{′} ( k ) \\ α\end{matrix} ] = {H}^{H} {X}^{′} ( k ) + {λ}^{*} α , \qquad ( 8 )$$

where λ is a new coefficient to optimize, α is a fixed parameter whose value is fixed and not adapted, and the subscript * denotes the complex conjugation. For optimum performance the fixed parameter α should be chosen to be similar in power level to the digital baseband samples. However, the choice of α is not critical and may take on any value depending on the particular application and overall design constraints.

Considering the added dimension, a modified MSE, a modified MSE computation can be represented as:

e(C)=e(H,λ)=E|y(k)−ŷ(k)|²=E|y(k)−C^{H}Z(k)|²=E|y(k)−H^{H}X′(k)−λ*α|² (9)

A modified LMS algorithm using a steepest descent search algorithm can then be employed to adapt the filter coefficients during the pilot sequence from the following algorithm derived from equation (9):

e(k)=y(k)−C^{H}(k)Z(k)=y(k)−H(k)^{H}X′(k)−αλ*(k)

$$C ( k + 1 ) = C ( k ) + μ Z ( k ) {e ( k )}^{H} = \{ \begin{matrix}H ( k + 1 ) = H ( k ) + μ {X}^{′} ( k ) {e ( k )}^{H} \\ λ ( k + 1 ) = λ ( k ) + μα {e ( k )}^{H}\end{matrix} \} \qquad ( 10 )$$

where

C^{H}(k)=[H λ];

Z(k)=[x′(k) α]^{H};

e(k) is an error, which is a difference between y(k) (from memory) and ŷ(k); and

μ is the gain constant (or an adaptation constant).

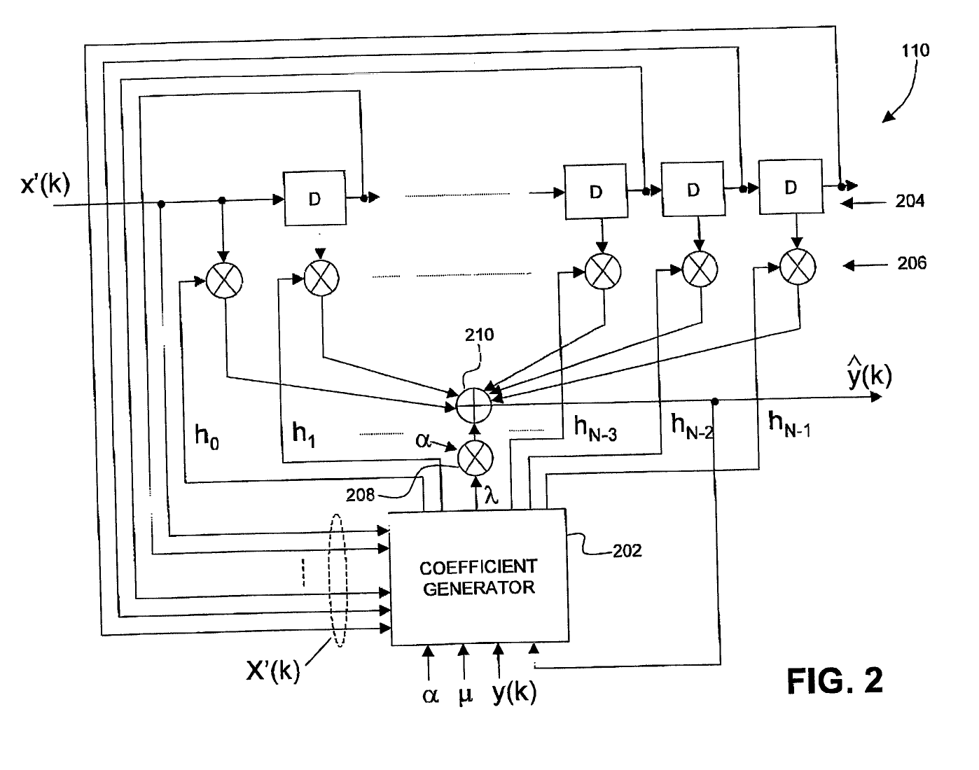

An exemplary adaptive filter that uses equation (8) to generate symbol estimates ŷ(k) is illustrated in FIG. 2. A coefficient generator 202 can be used to generate the filter coefficients including the new coefficient λ during the pilot sequence of the transmission using the modified LMS algorithm of equation (10).

A tapped delay line 204 can employ delay elements, such as shift registers, arranged in series to temporarily store the serial digital baseband samples from the ADC 108 (see FIG. 1). The generation of the soft symbol estimates ŷ(k) entails multiplying the output of each delay element with a filter coefficient using multipliers 206 (one for each delay element output) and multiplying the fixed parameter α with the new adapted coefficient λ with a multiplier 208. The outputs of the multipliers 206 and the multiplier 208 can then be summed with an adder 210 to produce the soft symbol estimates ŷ(k).

During the adaptation of the filter coefficients, the output of each delay element and the soft symbol estimates ŷ(k) are fed back to the coefficient generator 202. A locally generated pilot sequence y(k) can be provided to the coefficient generator 202 from a pilot sequence generator (not shown). The gain constant μ and the fixed parameter α can be provided to the coefficient generator 202 from a processor, memory, or any other device. From these inputs, the modified LMS algorithm can be used to adapt the filter coefficients during the pilot sequence of the transmission.

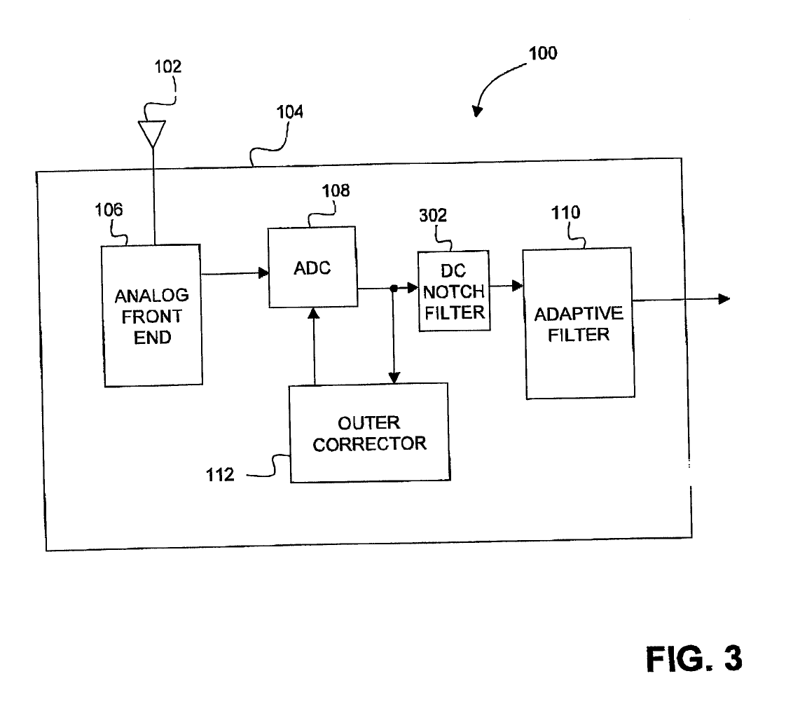

FIG. 3 is a functional block diagram of a communications device employing an exemplary receiver with a DC notch filter. A DC notch filter 302 may be placed at the input to the adaptive filter 110 to facilitate the convergence of the modified LMS algorithm by reducing large values of DC bias that might otherwise slow down the convergence of the filter coefficients due to an increase in the eigenvalue spread of the signal autocorrelation matrix. For the purposes of illustration, the DC notch filter 302 is shown at the input to the adaptive filter 110. However, as those skilled in the art will readily appreciate, the DC notch filter 302 could be placed at any other point in the receiver path.

There are various ways in which a DC notch filter 302 can be implemented, either digitally or with analog components. For example, the DC notch filter 302 may be implemented as an analog filter in the AFE 106 or as a digital filter after the ADC 108. It should be noted that the use of the DC notch filter 302 by itself, or together with an outer correction loop 112, may not totally remove the DC bias because any realizable filter may have residual bias at its output. However, when used in combination with an adaptive filter employing the modified LMS algorithm of equation (10), substantially no loss in receiver performance should be experienced due to DC bias.

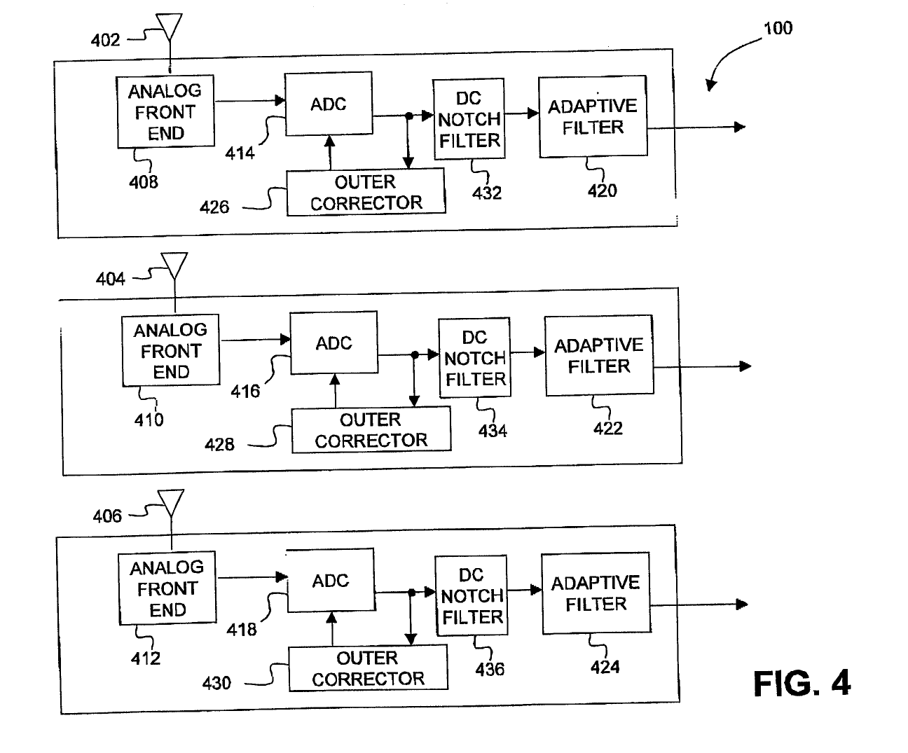

FIG. 4 is a functional block diagram of a communications device with an exemplary receiver architecture supporting multiple antennas. In this exemplary embodiment of a communications device, multiple antennas 402, 404, and 406 can be arranged for diversity reception in order to mitigate the effects of multipath interference and improve throughput. Each antenna has associated with it a respective AFE 408, 410, and 412, an ADC 414, 416, and 418, and an adaptive filter 420, 422, and 424. Further, each ADC 414, 416, and 418 can be respectively provided with an outer correction loop 426, 428, 430 to control clipping caused by excessive DC bias. Each of the ADCs 414, 416, and 418 may also have a DC notch filter 432, 434, and 436 positioned at its respective output. Alternatively, the DC notch filters can be located any where in the receive path and can be implemented as an analog or digital filter.

The outputs of the adaptive filters 420, 422, and 424 are combined across the antennas to estimate the k-th transmitted symbol y(k). The formulation of equations (2) and (3) still hold with the column vectors of the filter coefficients H and the digital baseband samples x(k) now being represented as follows:

$$H = [ \begin{matrix}{H}_{1} \\ {H}_{2} \\ ⋮ \\ {H}_{A}\end{matrix} ] , X ( k ) = [ \begin{matrix}{X}_{1} ( k ) \\ {X}_{2} ( k ) \\ ⋮ \\ {X}_{A} ( k )\end{matrix} ] , \qquad ( 11 )$$

where A is the number of antennas, and xᵢ (k) for i=1 . . . A represents the digital baseband samples from antenna i stacked in a vector of length N. It should be noted that the column vectors H and x(k) both have a length N×A.

Since the DC bias is, in general, different for each antenna, the representative equation for the digital baseband samples input to the adaptive filters becomes:

xᵢ′(k)=xᵢ(k)+b_{i′} (12)

for i=I . . . A, where the xᵢ(k) denote digital baseband samples from an ideal bias-free ADC and the x_{i′}(k) denote the actual digital baseband samples with DC bias that are input to the adaptive filters 420, 422 and 424.

It follows that the column vector for the actual digital baseband samples input into each of the adaptive filters is:

$$\begin{matrix} {X}^{′} ( k ) = X ( k ) + [ \begin{matrix}\begin{matrix}{b}_{1} \\ ⋮ \\ {b}_{1}\end{matrix} \} N \\ \begin{matrix}{b}_{2} \\ ⋮ \\ {b}_{2}\end{matrix} \} N \\ \begin{matrix}{b}_{A} \\ ⋮ \\ {b}_{A}\end{matrix} \} N\end{matrix} ] = X ( k ) + MB with B ≡ [ \begin{matrix}{b}_{1} \\ {b}_{2} \\ ⋮ \\ {b}_{A}\end{matrix} ] & ( 13 )\end{matrix}$$

Each row of M includes all zeros except for a 1 in the appropriate position to select the DC bias corresponding to that antenna out of the column vector for the DC bias B. By way of example, if N=3 and A=2,

$$M = [ \begin{matrix}1 & 0 \\ 1 & 0 \\ 1 & 0 \\ 0 & 1 \\ 0 & 1 \\ 0 & 1\end{matrix} ] \qquad ( 14 )$$

The modified LMS algorithm can now be expanded to adapt the filter coefficients including the new coefficient for each adaptive filter in accordance with equation (10).

The generality of the exemplary receiver described thus far can be extended to any communications system. By way of example, the exemplary receiver can be used in a CDMA communications system. A CDMA communications system is a modulation and multiple access scheme based on spread-spectrum communications. In a CDMA communications system, a large number of signals share the same frequency spectrum and, as a result, provide an increase in user capacity. This is achieved by transmitting each signal with a different pseudo-random binary sequence that modulates a carrier, and thereby, spreads the spectrum of the signal waveform. The transmitted signals are separated in the receiver by a demodulator that uses a corresponding pseudo-random binary sequence to despread the desired signal's spectrum. The undesired signals, whose pseudo-random binary sequence do not match, are not despread in bandwidth and contribute only to noise. The CDMA communications system can be implemented in a variety of fashions including the manner described in U.S. Pat. No. 4,901,307, entitled “Spread Spectrum Multiple Access Communication System Using Satellite or Terrestrial Repeaters,” or U.S. Pat. No. 5,103,459, entitled “System and Method for Generating Waveforms in a CDMA Cellular Telephone System,” both assigned to the assignee of the present invention and incorporated herein by reference.

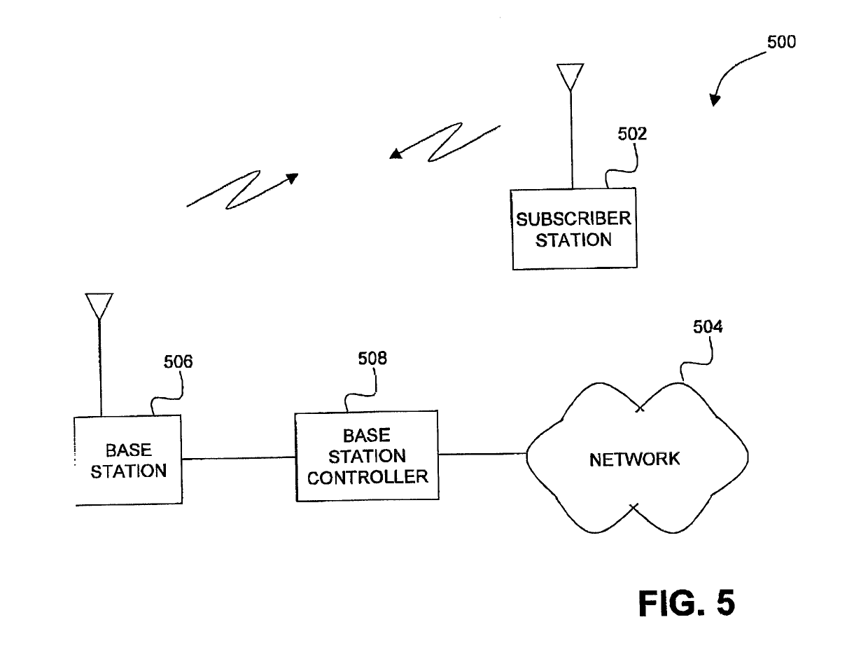

Various CDMA communications systems support a variable data rate request scheme. An exemplary communications system employing a variable rate data request scheme is shown in FIG. 5. The exemplary communications system 500 includes a subscriber station 502 in communication with a network 504 by transmitting data on a reverse link to a base station 506. The base station 506 receives the data and routes the data through a base station controller (BSC) 508 to the network 504. Conversely, communications to the subscriber station 502 can be routed from the network 504 to the base station 506 via the BSC 508 and transmitted from the base station 506 to the subscriber station 502 on a forward link.

A data rate control (DRC) message can be embedded in the reverse link transmission. The DRC message is typically a function of the carrier-to-interference (C/I) ratio of the forward link transmission estimated at the subscriber station based on the MSE. By eliminating the DC bias with a modified LMS algorithm, the resulting MSE may produce a better C/I estimate, which in turn, can support a higher data rate over the forward link through a DRC messaging process. With a higher forward link data rate, the bandwidth of the communications channel may be improved, thereby increasing overall user capacity and throughput of the communications system.

Initially, the subscriber station 502 establishes communication with the base station 506 using a predetermined access procedure. In this connected state, the subscriber station 502 can receive data and control messages from the base station 506, and is able to transmit data and control messages to the base station 506. The subscriber station 502 then estimates the C/I of the forward link transmission from the base station 506. The C/I of the forward link transmission can be obtained by measuring the strength of pilot sequence from the base station 506. Based on the C/I estimation, the subscriber station 502 can transmit to the base station 506 a DRC message over a dedicated channel on the reverse link. The base station 506 can use the DRC message from the subscriber station 502 to efficiently transmit the forward link data at the highest possible rate.

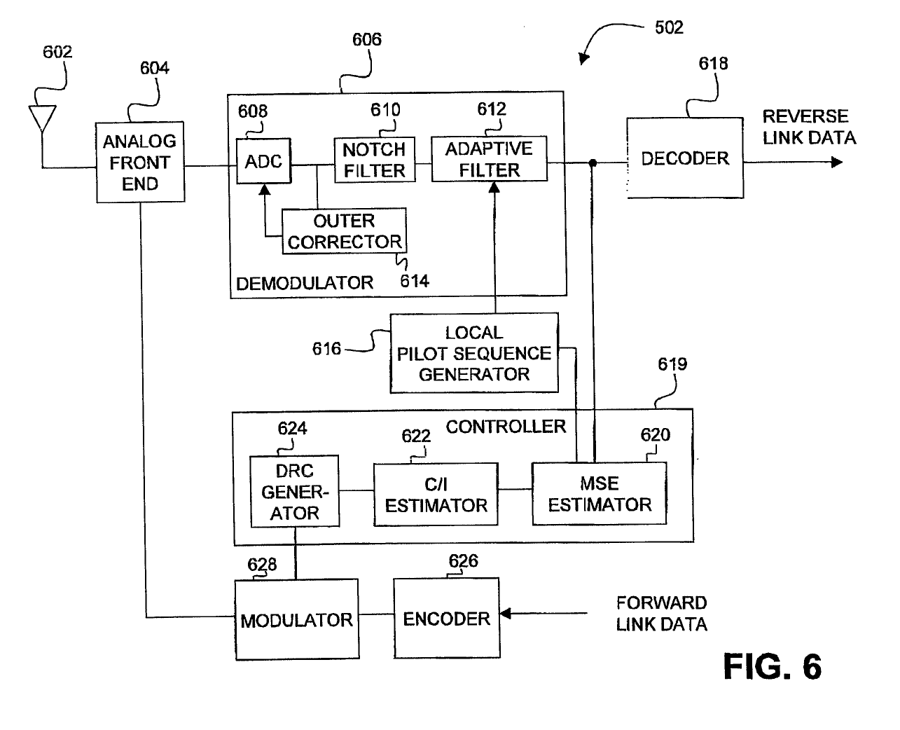

FIG. 6 is a functional block diagram of a subscriber station employing a receiver with an exemplary adaptive filter. The subscriber station 502 includes an antenna 602 configured to receive the forward link transmission. The forward link transmission received by the antenna 602 can be provided to an AFE 604. In the described exemplary communications device, the AFE 604 includes a transmitter output stage (not shown) and the analog front end circuitry for the receiver (not shown) each alternatively coupled to the antenna 602 with a diplexer (not shown). With the analog front end circuitry for the receiver coupled to the antenna 602, the received transmission can be amplified, filtered and downconverted to an analog baseband signal.

The analog baseband signal from the AFE 604 can be provided to a demodulator 606. The demodulator 606 includes an ADC 608, a notch filter 610, an adaptive filter 612, an outer correction loop 614, and carrier and timing recovery circuits (not shown). The ADC produces digital baseband samples from the analog baseband signal. The digital baseband samples from the ADC 608 can be provided to the adaptive filter 612. An outer correction loop 614 can be positioned at the output of the ADC 608 to control the clipping of the digital baseband samples should the DC bias become excessive. A DC notch filter 610 can be positioned between the ADC 608 and the adaptive filter 612 to facilitate the convergence of the modified LMS algorithm during the pilot sequence of the transmission. A local pilot sequence generator 616 can be used to generate a replica of the transmitted pilot sequence to adapt the filter coefficients including the new coefficient λ.

During the pilot sequence of the forward link transmission, the soft symbol estimates from the adaptive filter 612 can be provided to a controller 619 to generate the DRC message. The controller may include an MSE estimator 620 which computes the MSE based on the soft symbol estimates from the adaptive filter 610 and the locally generated pilot sequence from the local pilot sequence generator 616. The MSE can be computed by solving the following equation over the pilot sequence:

$$MSE = \frac{1}{N} {\sum }_{k = 1}^{N} {\vert y ( k ) - \hat{y} ( k ) \vert}^{2} \qquad ( 15 )$$

where N represents the number of pilot symbols.

A C/I estimator 622 can be used to compute the C/I from the estimated MSE by means well known in the art. In at least one embodiment of the subscriber station, the C/I computation can be performed in a way that accounts for the bias in the soft symbol estimates introduced by the adaptive filter itself. An example of a methodology for bias compensation is disclosed in U.S. patent application Ser. No. ______ Attorney Docket No. PD010168, entitled “Systems and Techniques for Measuring the Performance of a Communications System,” assigned to the assignee of the present invention and incorporated herein by reference. The estimated C/I can be provided to a DRC generator 624 to produce the DRC message. The DRC generator 624 can be a look-up table or other similar device which converts the estimated C/I into a digital code of one or more bits.

The DRC message from the controller 618 can then be provided to a modulator 628 where it can be covered with a Walsh code and time division multiplexed with another signal, such as the reverse link pilot signal. The DRC message and the pilot signal can then be spread with short pseudo-random noise (PN) codes and punctured into with the reverse link data. The reverse link data can is typically encoded and interleaved by an encoder 620, and covered with Walsh codes, spread with a long PN code, and further spread with the short PN codes in the modulator 628 before being punctured with the DRC message. The reverse link data carrying the DRC message can then be provided to the transmitter output stage (not shown) in the AFE 604 for upconversion, filtering and amplification for over the air transmission, through the antenna 602, over the reverse link.

Those skilled in the art will appreciate that the various illustrative logical blocks, modules, circuits, and algorithms described in connection with the embodiments disclosed herein may be implemented as electronic hardware, computer software, or combinations of both. To clearly illustrate this interchangeability of hardware and software, various illustrative components, blocks, modules, circuits, and algorithms have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method of filtering a plurality of samples, comprising:
adapting a plurality of filter coefficients; and
filtering a plurality of samples by applying one of the filter coefficients to a parameter, applying each remaining filter coefficient to one of the samples, and combining the parameter and the samples;
wherein the adaptation of the filter coefficients is a function of the combined parameter and samples.

2. The method of claim 1 wherein the filtering of samples multiplying said one of the filter coefficients with the parameter, multiplying each of the remaining filter coefficients with its respective sample, and summing the parameter and the samples.

3. The method of claim 1 wherein the adaptation of the filter coefficients comprising using a least square algorithm.

4. The method of claim 3 wherein the least square algorithm comprises a least mean square (LMS) algorithm.

5. The method of claim 1 wherein the parameter comprises a fixed value.

6. The method of claim 5 wherein the samples comprise an average value, and wherein the fixed value of the parameter is substantially equal to the average value of the samples.

7. The method of claim 1 further comprising monitoring a DC bias of the samples, and reducing the DC bias if it exceeds a threshold.

8. The method of claim 1 further comprising notch filtering the samples.

9. The method of claim 8 wherein the notch is substantially at DC.

10. The method of claim 1 wherein the adaptation of the filter coefficients is further a function of a plurality of locally generated samples.

11. The method of claim 10 wherein the adaptation of the filter coefficients further comprises applying a minimum mean square error algorithm to the filtered samples and the locally generated samples.

12. A receiver, comprising:
an analog-to-digital converter configured to sample an analog signal to produce a plurality of samples; and
a filter having a coefficient generator configured to adapt a plurality of filter coefficients, the filter being configured to apply one of the filter coefficients to a parameter, apply each of the remaining filter coefficients to one of the samples, and combine the parameter and the samples, the adaptation of the filter coefficients being a function of the combined parameter and samples.

13. The receiver of claim 12 wherein the filter further comprises a first multiplier configured to multiply said one of the filter coefficients with the parameter, a second multiplier configured to multiply each of the remaining filter coefficients with its respective sample, and an adder configured to sum the parameter and the samples.

14. The receiver of claim 13 wherein the filter further comprises a delay element configured to serially receive the samples from the analog-to-digital converter, and wherein the second multiplier is further configured to multiply each of the remaining filter coefficients with its respective sample from the delay element.

15. The receiver of claim 12 wherein the coefficient generator is further configured to adapt the filter coefficients using a least square algorithm.

16. The receiver of claim 15 wherein the least square algorithm comprises a least mean square (LMS) algorithm.

17. The receiver of claim 12 wherein the parameter comprises a fixed value.

18. The receiver of claim 17 wherein the samples comprise an average value, and wherein the fixed value of the parameter is substantially equal to the average value of the samples.

19. The receiver of claim 12 further comprising an outer correction loop configured to monitoring a DC bias of the samples generated by the analog-to-digital converter, and reducing the DC bias if it exceeds a threshold.

20. The receiver of claim 12 further comprising a notch filter configured to filter the samples.

21. The receiver of claim 12 further comprising a notch filter configured to filter the samples.

22. The receiver of claim 21 wherein the notch filter is further configured with a notch substantially at DC.

23. The receiver of claim 12 wherein the receiver further comprises a sample generator configured to generate a plurality of locally generated samples, and wherein the coefficient generator is further configured to adapt the filter coefficient as a function of the locally generated samples.

24. The method of claim 23 wherein the coefficient generator is further configured to adapt the filter coefficients by applying a minimum mean square error algorithm to the filtered samples and the locally generated samples.

25. A filter, comprising:
a delay element configured to serially receive a plurality of samples;
a coefficient generator configured to adapt a plurality of coefficients;
a first multiplier configured to multiply said one of the filter coefficients with the parameter;
a second multiplier configured to multiply each remaining filter coefficient with one of the samples from the delay element; and
an adder configured to sum the parameter and the samples;
wherein the adaptation of the filter coefficients is a function of the summed parameter and samples.

26. The filter of claim 25 wherein the coefficient generator is further configured to adapt the filter coefficients using a least square algorithm.

27. The filter of claim 26 wherein the least square algorithm comprises a least mean square (LMS) algorithm.

28. The filter of claim 25 wherein the parameter comprises a fixed value.

29. The filter of claim 28 wherein the samples comprise an average value, and wherein the fixed value of the parameter is substantially equal to the average value of the samples.

30. The filter of claim 25 wherein the coefficient generator is further configured to receiver a plurality of locally generated samples, and adapt the filter coefficient as a function of the locally generated samples.

31. The filter of claim 30 wherein the coefficient generator is further configured to adapt the filter coefficients by applying a minimum mean square error algorithm to the filtered samples and the locally generated samples.

32. Computer-readable media embodying a program of instructions executable by a computer program to perform a method of adapting filter coefficients, the method comprising:
adapting a plurality of filter coefficients; and
filtering a plurality of samples by applying one of the filter coefficients to a parameter, applying each remaining filter coefficient to one of the samples, and combining the parameter and the samples;
wherein the adaptation of the filter coefficients is a function of the combined parameter and samples.

33. The computer-readable media of claim 32 wherein the filtering of samples multiplying said one of the filter coefficients with the parameter, multiplying each of the remaining filter coefficients with its respective sample, and summing the parameter and the samples.

34. The computer-readable media of claim 32 wherein the adaptation of the filter coefficients comprising using a least square algorithm.

35. The computer-readable media of claim 34 wherein the least square algorithm comprises a least mean square (LMS) algorithm.

36. The computer-readable media of claim 32 wherein the parameter comprises a fixed value.

37. The computer-readable media of claim 36 wherein the samples comprise an average value, and wherein the fixed value of the parameter is substantially equal to the average value of the samples.

38. The computer-readable media of claim 32 wherein the adaptation of the filter coefficients is further a function of a plurality of locally generated samples.

39. The computer-readable media of claim 38 wherein the adaptation of the filter coefficients further comprises applying a minimum mean square error algorithm to the filtered samples and the locally generated samples.

40. A filter, comprising:
means for adapting a plurality of filter coefficients; and
means for filtering a plurality of samples by applying one of the filter coefficients to a parameter, applying each of the remaining filter coefficients to one of the samples and combining the parameter and the samples;
wherein the adaptation of the filter coefficients is a function of the combined parameter and samples.

41. The filter of claim 40 wherein the means for filtering the samples comprises means for multiplying said one of the filter coefficients with the parameter, means for multiplying each of the remaining filter coefficients with its respective sample, and means for summing the parameter and the samples.

42. The filter of claim 41 wherein the means for filtering the samples further comprises means for serially receiving the samples.

43. The filter of claim 40 wherein the means for adapting the filter coefficients uses a least square algorithm.

44. The filter of claim 43 wherein the least square algorithm comprises a least mean square (LMS) algorithm.

45. The filter of claim 40 wherein the parameter comprises a fixed value.

46. The filter of claim 45 wherein the samples comprise an average value, and wherein the fixed value of the parameter is substantially equal to the average value of the samples.

47. The filter of claim 40 wherein the adaptation of the filter coefficients are further a function of the locally generated samples.

48. The filter of claim 47 wherein the adaptation of the filter coefficients are performed by applying a minimum mean square error algorithm to the filtered samples and the locally generated samples.
